(19) United States
(12) Patent Application Publication
(10) Pub. No.: US 2025/0174397 A1
(43) Pub. Date: May 29, 2025

(54) CAPACITOR EMBEDDED SUBSTRATE

(71) Applicant: Murata Manufacturing Co., Ltd., Nagaokakyo-shi (JP)

(72) Inventors: Shuhei YAMADA, Nagaokakyo-shi (JP); Takaaki SAKAI, Nagaokakyo-shi (JP)

(21) Appl. No.: 19/027,718

(22) Filed: Jan. 17, 2025

Related U.S. Application Data
(63) Continuation of application No. PCT/JP2024/007030, filed on Feb. 27, 2024.

(30) Foreign Application Priority Data
Mar. 9, 2023 (JP) 2023-036657

(51) Int. Cl. H01G 2/06; H01G 9/008; H01G 9/10

(52) U.S. Cl. CPC H01G 2/06; H01G 9/008; H01G 9/10

(57) ABSTRACT

A capacitor embedded substrate that includes: a core substrate that includes a base that defines an opening in a thickness direction; a capacitor component in the opening of the core substrate; and a sealing member sealing the core substrate and the capacitor component, wherein the capacitor component includes a capacitor main body, a through conductor in a through-hole penetrating the capacitor main body in the thickness direction, and a conductor wiring layer on opposed end portions of the through conductor in the thickness direction, a first surface of the core substrate and a first surface of the capacitor component exist on a same plane, and a diameter of an end portion of the through-hole on a first sealing portion side is larger than a diameter of an end portion of the through-hole on a second sealing portion side.

### CROSS REFERENCE TO RELATED APPLICATIONS

The present application is a continuation of International application No. PCT/JP2024/007030, filed Feb. 27, 2024, which claims priority to Japanese Patent Application No. 2023-036657, filed Mar. 9, 2023, the entire contents of each of which are incorporated herein by reference.

### TECHNICAL FIELD

The present disclosure relates to a capacitor embedded substrate.

### BACKGROUND ART

Patent Document 1 discloses a wiring board including: a core substrate which is formed of an insulation material; and first insulating layers which are stacked on a first main surface side of the core substrate and on a second main surface side of the core substrate being opposite to the first main surface, in which a cavity in which a via conductor structure including a second base and a first through-hole conductor formed to penetrate the second base is disposed is formed in the core substrate, in the core substrate, a second through-hole conductor which penetrates the core substrate and the first insulating layer is formed in a region other than the cavity, and a wiring density of the first through-hole conductor is larger than a wiring density of the second through-hole conductor.
Patent Document 1: Japanese Unexamined Patent Application Publication No. 2014-165218

### SUMMARY OF THE DISCLOSURE

In the wiring board described in FIG. 1B and the like of Patent Document 1, the via conductor structure including the second base and the first through-hole conductor is sealed with an insulation layer in the state of being provided in the cavity of the core substrate. In manufacturing the wiring board described in FIG. 1B and the like of Patent Document 1, in a step before preparing the state where the via conductor structure is provided in the cavity of the core substrate, the via conductor structure is placed on a supporting plate as shown in FIG. 6A and the like of Patent Document 1. However, in the method described in FIG. 6A and the like of Patent Document 1, there is a possibility that in the first through-hole conductor, particularly a conductor portion located in an end portion of the first through-hole conductor on the supporting plate side is broken in the first through-hole conductor by a pressure at the time of placing the via conductor structure on the supporting plate.

Against this, it can be considered to increase the diameter of the first through-hole conductor in the wiring board described in FIG. 1B and the like of Patent Document 1 so as to disperse the pressure applied from the supporting plate to the first through-hole conductor. However, if the diameter of the first through-hole conductor is increased as a whole in the via conductor structure which is included in the wiring board described in FIG. 1B and the like of Patent Document 1, the area of the second base decreases as a whole. In this case, when the via conductor structure is a capacitor component, since the area of a portion which can exhibit the electrostatic capacity decreases as a whole in the second base, there is a possibility that the electrostatic capacity of the capacitor component decreases.

The present disclosure has been made to solve the above-described problem, and an object thereof is to provide a capacitor embedded substrate which can suppress both breakage of a through conductor and a conductor wiring layer provided on an end portion thereof, and a decrease in electrostatic capacity.

A capacitor embedded substrate of the present disclosure includes: a core substrate that includes a base that defines an opening in a thickness direction thereof; a capacitor component in the opening of the core substrate; and a sealing member which seals the core substrate and the capacitor component, wherein the capacitor component includes a capacitor main body having a positive electrode layer with a core portion, a dielectric layer, and a negative electrode layer opposite to the positive electrode layer with the dielectric layer interposed therebetween in the thickness direction, a through conductor at least on an inner-wall surface of a through-hole penetrating at least the capacitor main body in the thickness direction, and a conductor wiring layer on first and second opposed end portions of the through conductor in the thickness direction, the sealing member includes a first sealing portion which covers first surfaces respectively of the core substrate and the capacitor component and a second sealing portion which covers second surfaces respectively of the core substrate and the capacitor component in the thickness direction, the first surface of the core substrate and the first surface of the capacitor component exist on a same plane, and a diameter of an end portion of the through-hole on a first sealing portion side is larger than a diameter of an end portion of the through-hole on a second sealing portion side.

The present disclosure can provide a capacitor embedded substrate which can suppress both breakage of a through conductor and a conductor wiring layer provided on an end portion thereof, and a decrease in electrostatic capacity.

### BRIEF DESCRIPTION OF DRAWINGS

FIG. 1 is a sectional schematic diagram showing an example of a capacitor embedded substrate of Embodiment 1 of the present disclosure.

FIG. 2 is a sectional schematic diagram showing an example of a capacitor embedded substrate of Embodiment 2 of the present disclosure.

FIG. 3 is a sectional schematic diagram showing an example of a capacitor embedded substrate of modification of Embodiment 2 of the present disclosure.

FIG. 4 is a sectional schematic diagram showing an example of a capacitor embedded substrate of Embodiment 3 of the present disclosure.

FIG. 5 is a sectional schematic diagram showing an example of a capacitor embedded substrate of Embodiment 4 of the present disclosure.

### DESCRIPTION OF THE PREFERRED EMBODIMENTS

Hereinafter, capacitor embedded substrates of the present disclosure will be described. Note that the present disclosure is not limited to the following configurations, and may be modified as appropriate without departing from the gist of the present disclosure. In addition, those obtained by combining multiple ones of the individual preferable configurations described below are also encompassed by the present disclosure.

Each Embodiment shown below is illustrative, and it goes without saying that partial replacements or combinations of the configurations shown in different Embodiments are possible. From Embodiment 2 and below, the descriptions of the matters common to Embodiment 1 will be omitted, and different points will be mainly described. In particular, the same actions and effects as those obtained by the same configurations will not be described every time for each Embodiment.

In the following descriptions, when Embodiments are not particularly distinguished from one another, each Embodiment is described simply as the “capacitor embedded substrate of the present disclosure”.

The drawings shown below are schematic diagrams, and their dimensions, scales of aspect ratios, and the like are sometimes different from those of actual products.

In the present Specification, unless otherwise noted, terms indicating relations among elements (for example, “perpendicular”, “parallel”, and the like) and terms indicating the shapes of the elements do not only mean literally strict aspects but also mean substantially equivalent ranges, for example, ranges including differences of about several %.

A capacitor embedded substrate of the present disclosure includes: a core substrate that includes a base that defines an opening in a thickness direction thereof; a capacitor component in the opening of the core substrate; and a sealing member which seals the core substrate and the capacitor component, wherein the capacitor component includes a capacitor main body having a positive electrode layer with a core portion, a dielectric layer, and a negative electrode layer opposite to the positive electrode layer with the dielectric layer interposed therebetween in the thickness direction, a through conductor at least on an inner-wall surface of a through-hole penetrating at least the capacitor main body in the thickness direction, and a conductor wiring layer on first and second opposed end portions of the through conductor in the thickness direction, the sealing member includes a first sealing portion which covers first surfaces respectively of the core substrate and the capacitor component and a second sealing portion which covers second surfaces respectively of the core substrate and the capacitor component in the thickness direction, the first surface of the core substrate and the first surface of the capacitor component exist on a same plane, and a diameter of an end portion of the through-hole on a first sealing portion side is larger than a diameter of an end portion of the through-hole on a second sealing portion side.

### Embodiment 1

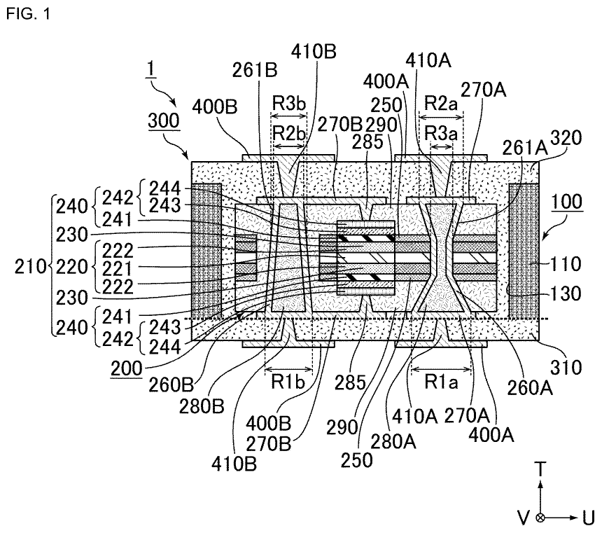

FIG. 1 is a sectional schematic diagram showing an example of a capacitor embedded substrate of Embodiment 1 of the present disclosure.

The capacitor embedded substrate 1 shown in FIG. 1 has a core substrate 100, a capacitor component 200, and a sealing member 300.

The core substrate 100 includes a base 110. In the example shown in FIG. 1, the core substrate 100 includes only the base 110.

In the base 110, an opening (also referred to as a cavity) 130 is provided in a thickness direction T. That is, in the core substrate 100, the opening 130 is provided. In the example shown in FIG. 1, the opening 130 penetrates the core substrate 100, specifically the base 110 in the thickness direction T.

The number of the opening 130 provided in the core substrate 100 may be one or more.

The base 110 is preferably formed of an insulating material. That is, the base 110 is preferably an insulating base.

The insulating material for forming the base 110 may contain an insulating resin, a prepreg, an inorganic material, a mixture of these, or the like.

The insulating resin contained in the insulating material for forming the base 110 includes, for example, epoxy resin, polyester resin, bismaleimide-triazine resin, polyimide resin, phenol resin, allyl polyphenylene ether resin, and the like.

The prepreg contained in the insulating material for forming the base 110 includes, for example, resin-impregnated glass fibers (resin-impregnated glass cloth) and the like.

Regarding the prepreg contained in the insulating material for forming the base 110, a diameter of the glass fibers (glass cloth) in the prepreg is preferably 3 μm to 15 μm.

Regarding the prepreg contained in the insulating material for forming the base 110, the content of the resin in the prepreg is preferably 50% by weight to 90% by weight.

The inorganic material contained in the insulating material for forming the base 110 includes, for example, glass and the like.

The capacitor component 200 is provided in the opening 130 of the core substrate 100.

Note that in the case where a plurality of the openings 130 are provided in the core substrate 100, the capacitor component 200 may be provided in each of the openings 130. Alternatively, the capacitor component 200 may be provided in some of the openings 130 with another electronic component different from the capacitor component 200 being provided in the remaining opening 130.

The capacitor component 200 includes a capacitor main body 210, a through conductor 260A, a through conductor 260B, a conductor wiring layer 270A, and a conductor wiring layer 270B.

The capacitor main body 210 includes a positive electrode layer 220, dielectric layers 230, and negative electrode layers 240.

Hereinafter, an example of an aspect in which the capacitor main body 210 forms an electrolytic capacitor will be described. Note that the capacitor main body 210 may form a capacitor other than an electrolytic capacitor.

The positive electrode layer 220 includes a core portion 221 and porous portions 222.

In the present Specification, the core portion of the positive electrode layer means a portion where a void such as a porous portion substantially does not exist, and preferably forms a center portion in the thickness direction of the positive electrode layer.

The core portion 221 is preferably formed of a metal, and is preferably formed of a valve metal among metals. In the case where the core portion 221 is formed of a valve metal, the positive electrode layer 220 is also referred to as a valve metal substrate.

The valve metal for forming the core portion 221 includes, for example, elementary metals such as aluminum, tantalum, niobium, titanium, and zirconium, alloys containing at least one of these elementary metals, and the like. Among these, aluminum or an aluminum alloy is preferable.

The porous portion 222 is provided on at least one surface of both surfaces of the core portion 221 on the opposite sides in the thickness direction T. That is, the porous portion 222 may be provided only on one surface of the core portion 221 or may be provided on both surfaces of the core portion 221. In this way, the positive electrode layer 220 includes the porous portion 222 at least on one surface among both surfaces on the opposite sides in the thickness direction T. This increases the surface area of the positive electrode layer 220, thus making it easier to improve the capacity of the capacitor main body 210.

The porous portion 222 is preferably an etching layer obtained by etching the surface of the positive electrode layer 220 (core portion 221).

The shape of the positive electrode layer 220 is preferably a flat-plate shape (positive electrode plate), and is more preferably a foil shape (positive electrode foil).

In the present Specification, the plate shape includes a foil shape, a sheet shape, a film shape, and the like, and these are not distinguished by the dimension in the thickness direction.

The dielectric layer 230 is provided on the surface of the porous portions 222. Specifically, the dielectric layer 230 is provided along the surfaces (contours) of pores present in the porous portion 222.

The dielectric layer 230 is preferably formed of an oxide film of the above-mentioned valve metal. For example, in the case where the positive electrode layer 220 is an aluminum foil, an oxide film which will become the dielectric layer 230 is formed by conducting an anodization process (also referred to as a chemical conversion process) on the aluminum foil in an aqueous solution containing ammonium adipate or the like. Since the dielectric layer 230 is formed along the surface of the porous portion 222, pores (recesses) are provided in the dielectric layer 230.

The negative electrode layer 240 faces the positive electrode layer 220 with the dielectric layer 230 interposed therebetween in the thickness direction T.

The negative electrode layer 240 is provided on the surface of the dielectric layer 230.

The negative electrode layer 240 preferably includes a solid electrolyte layer 241 which is provided on the surface of the dielectric layer 230 and a conductor layer 242 which is provided on the surface of the solid electrolyte layer 241. In the case where the negative electrode layer 240 includes the solid electrolyte layer 241, the capacitor main body 210 forms a solid electrolytic capacitor.

The solid electrolyte layer 241 preferably includes an inner layer which is provided inside the pores of the dielectric layer 230 and an outer layer which covers the inner layer.

The constituent material of the solid electrolyte layer 241 includes, for example, conductive polymers such as polypyrroles, polythiophenes, and polyanilines, and the like. Among these, polythiophenes are preferable, and poly(3,4-ethylenedioxythiophene) (PEDOT) is particularly preferable. In addition, the conductive polymer may contain a dopant such as polystyrene sulfonate (PSS).

The solid electrolyte layer 241 is formed in a predetermined region on the surface of the dielectric layer 230 by, for example, a method including applying a dispersion liquid of a conductive polymer such as poly(3,4-ethylenedioxythiophene) on the surface of the dielectric layer 230 and drying the dispersion liquid, a method including forming a polymerized film of poly(3,4-ethylenedioxythiophene) or the like on the surface of the dielectric layer 230 by using a treatment liquid containing a polymerizable monomer such as 3,4-ethylenedioxythiophene, or the like.

The conductor layer 242 preferably includes a conductive resin layer 243 which is provided on the surface of the solid electrolyte layer 241 and a metal layer 244 which is provided on the surface of the conductive resin layer 243.

The conductive resin layer 243 includes, for example, a conductive adhesive layer which contains at least one conductive filler selected from the group consisting of a copper filler, a silver filler, a nickel filler, and a carbon filler, and the like.

The metal layer 244 preferably contains a metal filler.

The metal filler contained in the metal layer 244 is preferably at least one selected from the group consisting of a copper filler, a silver filler, and a nickel filler.

The metal layer 244 may be, for example, a metal plating film, a metal foil, or the like. In this case, the metal layer 244 is preferably formed of at least one metal selected from the group consisting of copper, silver, nickel, and an alloy containing at least one of these metals as a main component.

In the present Specification, the main component means an element component having the largest proportion by weight.

The conductor layer 242 may include, for example, a carbon layer as the conductive resin layer 243 and a copper layer as the metal layer 244.

The carbon layer is formed in a predetermined region by, for example, applying a carbon paste containing a carbon filler onto the surface of the solid electrolyte layer 241 by a sponge transfer method, a screen printing method, a dispenser coating method, an inkjet printing method, or the like.

The copper layer is formed in a predetermined region by, for example, applying a copper paste containing a copper filler onto the surface of the carbon layer by a sponge transfer method, a screen printing method, a spray coating method, a dispenser coating method, an inkjet printing method, or the like.

The conductor layer 242 may include at least one of the conductive resin layer 243 and the metal layer 244. That is, the conductor layer 242 may include only the conductive resin layer 243, or may include only the metal layer 244, or may include both of the conductive resin layer 243 and the metal layer 244.

The capacitor main body 210 preferably further includes a mask layer 250 which is provided on a peripheral edge of the porous portion 222 as viewed in the thickness direction T.

The mask layer 250 is preferably provided on the entire peripheral edge of the porous portion 222 as viewed in the thickness direction T. Note that the mask layer 250 may be provided on part of the peripheral edge of the porous portion 222 as viewed in the thickness direction T.

The mask layer 250 is preferably provided in such a manner as to extend inward from at least one surface of both surfaces of the positive electrode layer 220, and is more preferably provided in such a manner as to extend inward from both surfaces of the positive electrode layer 220, in the thickness direction T.

The mask layer 250 may be in contact with the core portion 221, or may be separate from the core portion 221, in the thickness direction T.

The mask layer 250 may be provided outside the porous portion 222 in addition to inside the porous portion 222. In this case, the mask layer 250 may be provided on the surface of the porous portion 222 filled with the mask layer 250 while being put inside the porous portion 222. That is, the thickness of the mask layer 250 may be larger than the thickness of the porous portion 222.

In the case where the mask layer 250 is provided outside the porous portion 222, the mask layer 250 is preferably provided in a region which surrounds the negative electrode layer 240 as viewed in the thickness direction T.

The mask layer 250 may be placed partially on the negative electrode layer 240, or does not have to be placed entirely on the negative electrode layer 240, as viewed in the thickness direction T.

The mask layer 250 is preferably formed of an insulating material. In this case, the insulation between the positive electrode layer 220 and the negative electrode layer 240 is sufficiently secured, and short-circuiting therebetween is sufficiently prevented.

The insulating material for forming the mask layer 250 includes, for example, polyphenylsulfone (PPS), polyethersulfone (PES), cyanate ester resin, fluororesins (tetrafluoroethylene, tetrafluoroethylene·perfluoroalkyl vinyl ether copolymer, and the like), a composition composed of soluble polyimide siloxane and epoxy resin, polyimide resin, polyamideimide resin, derivatives or precursors of these, and the like.

The mask layer 250 is formed on a peripheral edge of the porous portion 222, for example, by applying the above-mentioned insulating material at positions overlapping the peripheral edges of the porous portion 222 in both surfaces of the positive electrode layer 220, and causing the insulating material to penetrate inward from both surfaces of the positive electrode layer 220.

The mask layer 250 may be formed at a timing before the dielectric layer 230 is formed, or may be formed at a timing after the dielectric layer 230 is formed, on the porous portion 222.

The planar shape of the capacitor main body 210 as viewed in the thickness direction T includes, for example, a rectangle (a square or an oblong), a quadrangle other than a rectangle, a polygon such as a triangle, a pentagon, or a hexagon, a circle, an ellipse, and the like.

The number of the capacitor main body 210 in the capacitor component 200 may be one or more.

In the case where there are a plurality of the capacitor main bodies 210 in the capacitor component 200, the plurality of capacitor main bodies 210 are preferably planarly arranged in a plane direction which is perpendicular to the thickness direction T. In the example shown in FIG. 1, the plane direction is a direction encompassing a first direction U which is perpendicular to the thickness direction T and a second direction V which is perpendicular to the thickness direction T and the first direction U.

In the case where a plurality of the capacitor main bodies 210 are planarly arranged in the plane direction, the plurality of capacitor main bodies 210 may be planarly arranged along a plurality of directions among the plane direction, or may be planarly arranged in one direction among the plane direction. In addition, the plurality of capacitor main bodies 210 may be planarly arranged regularly, or may be planarly arranged irregularly.

In the case where there are a plurality of the capacitor main bodies 210 in the capacitor component 200 as described above, the capacitor component 200 may form a capacitor array in which the plurality of capacitor main bodies 210 are arranged in an array pattern in the plane direction.

The through conductor 260A is provided on at least an inner-wall surface of a through-hole 261A which penetrates at least the capacitor main body 210 in the thickness direction T. In the example shown in FIG. 1, the through-hole 261A penetrates the capacitor main body 210 and a sealing layer 290, which will be described later, in the thickness direction T. In the example shown in FIG. 1, the through conductor 260A is provided on the inner-wall surface of the through-hole 261A.

The through conductor 260A may be provided only on the inner-wall surface of the through-hole 261A, or may be provided inside the entire through-hole 261A.

In the case where the through conductor 260A is provided only on the inner-wall surface of the through-hole 261A, a space surrounded by the through conductor 260A in the through-hole 261A may be filled with a resin material. That is, the capacitor component 200 may further include a resin-filled portion 280A which is provided in the space surrounded by the through conductor 260A in the through-hole 261A. When the space in the through-hole 261A is eliminated by providing the resin-filled portion 280A, the occurrence of delamination of the through conductor 260A is suppressed.

The coefficient of thermal expansion of the resin-filled portion 280A is preferably higher than the coefficient of thermal expansion of the through conductor 260A. Specifically, the coefficient of thermal expansion of the constituent material (resin material) of the resin-filled portion 280A is preferably higher than the coefficient of thermal expansion of the constituent material of the through conductor 260A. In this case, when the resin-filled portion 280A (specifically, the constituent material (resin material) of the resin-filled portion 280A) expands in a high-temperature environment, the through conductor 260A is pressed against the inner-wall surface of the through-hole 261A from the inside of the through-hole 261A toward the outside, so that the occurrence of delamination of the through conductor 260A is sufficiently suppressed.

Note that the coefficient of thermal expansion of the resin-filled portion 280A may be equal to the coefficient of thermal expansion of the through conductor 260A, or may be lower than the coefficient of thermal expansion of the through conductor 260A.

Note that the capacitor component 200 does not have to include the resin-filled portion 280A. In this case, the through conductor 260A is preferably provided inside the entire through-hole 261A.

The through conductor 260A is preferably electrically connected to the positive electrode layer 220.

The through conductor 260A is preferably electrically connected to an end surface of the positive electrode layer 220 which faces the inner-wall surface of the through-hole 261A in the plane direction. In the example shown in FIG. 1, the through conductor 260A is directly connected to the end surface of the positive electrode layer 220.

On the end surface of the positive electrode layer 220 which is electrically connected to the through conductor 260A, the core portion 221 and the porous portion 222 are preferably exposed. In this case, in addition to the core portion 221, the porous portion 222 is also electrically connected to the through conductor 260A.

The through conductor 260A is preferably electrically connected to the positive electrode layer 220 across the entire periphery of the through-hole 261A as viewed in the thickness direction T. In this case, since the connection resistance between the positive electrode layer 220 and the through conductor 260A is likely to decrease, the equivalent series resistance (ESR) of the capacitor component 200 becomes likely to decrease.

The through conductor 260A may be electrically connected to the positive electrode layer 220 via a positive-electrode connection layer. In this case, the positive-electrode connection layer is preferably provided between the positive electrode layer 220 and the through conductor 260A in the plane direction. In this case, the positive-electrode connection layer functions as a barrier layer for the positive electrode layer 220, specifically, a barrier layer for the core portion 221 and the porous portion 222. When the positive-electrode connection layer functions as a barrier layer for the positive electrode layer 220, dissolution of the positive electrode layer 220, which would occur at the time of a chemical solution treatment for forming the conductor wiring layer 270A and the like, is suppressed, and in turn, the infiltration of a chemical solution into the capacitor main body 210 is suppressed, so that the reliability of the capacitor component 200 becomes likely to be improved.

The constituent material of the through conductor 260A includes, for example, a metal material containing a low-resistance metal such as copper, gold, or silver, a composite material of the above-described metal and a resin, and the like.

The planar shape of the through-hole 261A as viewed in the thickness direction T includes, for example, a circle, an ellipse, a rectangle (a square or an oblong), and the like.

The through conductor 260A is formed as follows, for example. First, the through-hole 261A which penetrates at least the capacitor main body 210 in the thickness direction T is formed by conducting laser machining or the like. Then, the through conductor 260A is formed by metalizing the inner-wall surface of the through-hole 261A with a metal material containing a low-resistance metal such as copper, gold, silver, or the like. When the through conductor 260A is formed, the processing is facilitated by metalizing the inner-wall surface of the through-hole 261A by means of an electroless copper plating process, an electrolytic copper plating process, or the like, for example. Note that the method for forming the through conductor 260A may be a method including filling the through-hole 261A with a metal material, a composite material of a metal and a resin, or the like, besides the method including metalizing the inner-wall surface of the through-hole 261A.

The through conductor 260B is provided at least on an inner-wall surface of a through-hole 261B, which penetrates at least the capacitor main body 210 in the thickness direction T, at a position where the through conductor 260B is electrically insulated from the through conductor 260A. In the example shown in FIG. 1, the through-hole 261B penetrates the capacitor main body 210 and the sealing layer 290, which will be described later, in the thickness direction T at a position separate from the through-hole 261A. In the example shown in FIG. 1, the through conductor 260B is provided on the inner-wall surface of the through-hole 261B.

The through conductor 260B may be provided only on the inner-wall surface of the through-hole 261B, or may be provided inside the entire through-hole 261B.

In the case where the through conductor 260B is provided only on the inner-wall surface of the through-hole 261B, a space surrounded by the through conductor 260B in the through-hole 261B may be filled with a resin material. That is, the capacitor component 200 may further include a resin-filled portion 280B which is provided in the space surrounded by the through conductor 260B in the through-hole 261B. When the space in the through-hole 261B is eliminated by providing the resin-filled portion 280B, the occurrence of delamination of the through conductor 260B is suppressed.

The coefficient of thermal expansion of the resin-filled portion 280B is preferably higher than the coefficient of thermal expansion of the through conductor 260B. Specifically, the coefficient of thermal expansion of the constituent material (resin material) of the resin-filled portion 280B is preferably higher than the coefficient of thermal expansion of the constituent material of the through conductor 260B. In this case, when the resin-filled portion 280B (Specifically, the constituent material (resin material) of the resin-filled portion 280B) expands in a high-temperature environment, the through conductor 260B is pressed against the inner-wall surface of the through-hole 261B from the inside of the through-hole 261B toward the outside, so that the occurrence of delamination of the through conductor 260B is sufficiently suppressed.

Note that the coefficient of thermal expansion of the resin-filled portion 280B may be equal to the coefficient of thermal expansion of the through conductor 260B, or may be lower than the coefficient of thermal expansion of the through conductor 260B.

Note that the capacitor component 200 does not have to include the resin-filled portion 280B. In this case, the through conductor 260B is preferably provided inside the entire through-hole 261B.

The through conductor 260B is preferably electrically connected to the negative electrode layer 240. In the example shown in FIG. 1, the through conductor 260B is electrically connected to the negative electrode layer 240 via the conductor wiring layer 270B and a via conductor 285, which will be described later.

A portion between the capacitor main body 210 and the through conductor 260B in the plane direction, in turn, a portion between the positive electrode layer 220 and the through conductor 260B in the plane direction is preferably filled with an insulating material of the sealing layer 290 or the like, which will be described later. In this case, the insulation between the positive electrode layer 220 and the through conductor 260B, in turn, the insulation between the positive electrode layer 220 and the negative electrode layer 240 is secured, and short-circuiting therebetween is prevented.

The constituent material of the through conductor 260B includes, for example, a metal material containing a low-resistance metal such as copper, gold, or silver, a composite material of the above-described metal and a resin, and the like.

The constituent materials of the through conductor 260A and the through conductor 260B may be the same or different.

The planar shape of the through-hole 261B as viewed in the thickness direction T includes, for example, a circle, an ellipse, a rectangle (a square or an oblong), and the like.

The planar shapes of the through-hole 261A and the through-hole 261B may be the same or different.

The through conductor 260B is formed as follows, for example. First, a through-hole which penetrates the capacitor main body 210 in the thickness direction T is formed by conducting laser machining or the like. Next, a sealing layer (for example, the sealing layer 290 which will be described later) with which at least the above-mentioned through-hole is filled is formed by sealing the capacitor main body 210 by using an insulating material or the like. Then, the through-hole 261B is formed by conducting laser machining or the like on the above-mentioned sealing layer. At this time, by making the diameter of the through-hole 261B smaller than the diameter of the through-hole formed first, a state in which the above-mentioned sealing layer is provided between an inner-wall surface of the through-hole formed first and the inner-wall surface of the through-hole 261B in the plane direction is obtained. Thereafter, the through conductor 260B is formed by metalizing the inner-wall surface of the through-hole 261B with a metal material containing a low-resistance metal such as copper, gold, silver, or the like. When the through conductor 260B is formed, the processing is facilitated by metalizing the inner-wall surface of the through-hole 261B by means of an electroless copper plating process, an electrolytic copper plating process, or the like, for example. Note that the method for forming the through conductor 260B may be a method including filling the through-hole 261B with a metal material, a composite material of a metal and a resin, or the like, besides the method including metalizing the inner-wall surface of the through-hole 261B.

The conductor wiring layer 270A is provided on both end portions of the through conductor 260A on the opposite sides in the thickness direction T.

The conductor wiring layer 270A is electrically connected to the through conductor 260A and functions as a connection terminal for the capacitor component 200. In the example shown in FIG. 1, the conductor wiring layer 270A is electrically connected to the positive electrode layer 220 via the through conductor 260A and functions as a connection terminal for the positive electrode layer 220.

The constituent material of the conductor wiring layer 270A includes, for example, a metal material containing a low-resistance metal such as copper, gold, or silver, and the like. In this case, the conductor wiring layer 270A is formed by plating both end portions of the through conductor 260A, for example.

In order to improve the adhesion between the conductor wiring layer 270A and another member, here the adhesion between the conductor wiring layer 270A and the through conductor 260A, a mixed material of at least one conductive filler selected from the group consisting of a silver filler, a copper filler, a nickel filler, and a carbon filler and a resin may be used as the constituent material of the conductor wiring layer 270A.

The conductor wiring layer 270B is provided on both end portions of the through conductor 260B on the opposite sides in the thickness direction T at a position where the conductor wiring layer 270B is electrically insulated from the conductor wiring layer 270A.

The conductor wiring layer 270B is electrically connected to the through conductor 260B and functions as a connection terminal of the capacitor component 200. In the example shown in FIG. 1, the conductor wiring layer 270B is electrically connected to the negative electrode layer 240 via the via conductor 285, which will be described later, and functions as the connection terminal for the negative electrode layer 240.

The constituent material of the conductor wiring layer 270B includes, for example, a metal material containing a low-resistance metal such as copper, gold, or silver, and the like. In this case, the conductor wiring layer 270B is formed by plating both end portions of the through conductor 260B, for example.

In order to improve the adhesion between the conductor wiring layer 270B and another member, here the adhesion between the conductor wiring layer 270B and the through conductor 260B, a mixed material of at least one conductive filler selected from the group consisting of a silver filler, a copper filler, a nickel filler, and a carbon filler and a resin may be used as the constituent material of the conductor wiring layer 270B.

The constituent materials of the conductor wiring layer 270A and the conductor wiring layer 270B may be the same or different.

The capacitor component 200 preferably further includes the sealing layer 290 which seals the capacitor main body 210. In this case, the capacitor main body 210 is protected by the sealing layer 290.

The sealing layer 290 preferably covers at least one surface of both surfaces of the capacitor main body 210 on the opposite sides in the thickness direction T, and more preferably covers both surfaces of the capacitor main body 210. In the example shown in FIG. 1, the sealing layer 290 covers the negative electrode layer 240 and the mask layer 250 included in both surfaces of the capacitor main body 210.

The sealing layer 290 is preferably placed on the entire capacitor main body 210 as viewed in the thickness direction T.

The sealing layer 290 may penetrate the capacitor main body 210 in the thickness direction T. In the example shown in FIG. 1, the sealing layer 290 penetrates the positive electrode layer 220, the dielectric layer 230, and the mask layer 250 in the thickness direction T.

The sealing layer 290 is preferably provided between the capacitor main body 210 and the through conductor 260B in the plane direction, in turn, between the positive electrode layer 220 and the through conductor 260B in the plane direction.

The sealing layer 290 is preferably in contact with both of the capacitor main body 210 and the through conductor 260B, in turn, both of the positive electrode layer 220 and the through conductor 260B, in the plane direction. In this case, the core portion 221 and the porous portion 222 are preferably exposed on the end surface of the positive electrode layer 220 which is in contact with the sealing layer 290. This increases the contact area between the porous portion 222 and the sealing layer 290 to improve the adhesion therebetween, so that failures such as peeling between the porous portion 222 and the sealing layer 290 become unlikely to occur.

In the case where the core portion 221 and the porous portion 222 are exposed on the end surface of the positive electrode layer 220 which is in contact with the sealing layer 290, it is preferable that the constituent material of the mask layer 250 enter the voids of the porous portion 222, so that the mask layer 250 spreads into the porous portion 222 and is provided around the through conductor 260B. In this case, the insulation between the positive electrode layer 220 and the through conductor 260B, in turn, the insulation between the positive electrode layer 220 and the negative electrode layer 240 is sufficiently secured, and short-circuiting therebetween is sufficiently prevented.

In the case where the core portion 221 and the porous portion 222 are exposed on the end surface of the positive electrode layer 220 which is in contact with the sealing layer 290, the constituent material of the sealing layer 290 preferably enters the voids of the porous portion 222. In this case, the mechanical strength of the porous portion 222 is improved, and the occurrence of delamination attributable to the voids of the porous portion 222 is suppressed.

The coefficient of thermal expansion of the sealing layer 290 is preferably higher than the coefficient of thermal expansion of the through conductor 260B. Specifically, the coefficient of thermal expansion of the constituent material of the sealing layer 290 is preferably higher than the coefficient of thermal expansion of the constituent material of the through conductor 260B. In this case, when the sealing layer 290 (Specifically, the constituent material of the sealing layer 290) expands in a high-temperature environment, the porous portion 222 and the through conductor 260B are pressed, so that the occurrence of delamination is sufficiently suppressed.

Note that the coefficient of thermal expansion of the sealing layer 290 may be equal to the coefficient of thermal expansion of the through conductor 260B, or may be lower than the coefficient of thermal expansion of the through conductor 260B.

In the case where there are a plurality of the capacitor main bodies 210 in the capacitor component 200, the sealing layer 290 may be put between adjacent capacitor main bodies 210 in such a manner as to separate the plurality of capacitor main bodies 210 from one another.

As described above, the sealing layer 290 is preferably provided in such a manner as to follow the shape of the surface of the capacitor main body 210.

The through-hole 261A preferably also penetrates the sealing layer 290 in addition to the capacitor main body 210 in the thickness direction T. In the example shown in FIG. 1, the through-hole 261A penetrates the capacitor main body 210 and the sealing layer 290 in the thickness direction T.

The through-hole 261B preferably also penetrates the sealing layer 290 in addition to the capacitor main body 210 in the thickness direction T. In the example shown in FIG. 1, the through-hole 261B penetrates the capacitor main body 210 and the sealing layer 290 in the thickness direction T.

The conductor wiring layer 270A is preferably provided also on both surfaces of the sealing layer 290 on the opposite sides in the thickness direction T in addition to on both end portions of the through conductor 260A. In the example shown in FIG. 1, the conductor wiring layer 270A is provided from both end portions of the through conductor 260A up to both surfaces of the sealing layer 290. Specifically, the conductor wiring layer 270A is provided from one end portion (a lower end portion in FIG. 1) of the through conductor 260A to one surface (a lower surface in FIG. 1) of the sealing layer 290, and is also provided from the other end portion (an upper end portion in FIG. 1) of the through conductor 260A to the other surface (an upper surface in FIG. 1) of the sealing layer 290.

The conductor wiring layer 270B is preferably provided also on both surfaces of the sealing layer 290 on the opposite sides in the thickness direction T in addition to on both end portions of the through conductor 260B. In the example shown in FIG. 1, the conductor wiring layer 270B is provided from both end portions of the through conductor 260B to both surfaces of the sealing layer 290. Specifically, the conductor wiring layer 270B is provided from one end portion (a lower end portion in FIG. 1) of the through conductor 260B to one surface (a lower surface in FIG. 1) of the sealing layer 290, and is also provided from the other end portion (an upper end portion in FIG. 1) of the through conductor 260B to the other surface (an upper surface in FIG. 1) of the sealing layer 290.

The sealing layer 290 is preferably formed of an insulating material.

The insulating material for forming the sealing layer 290 may contain an insulating resin.

The insulating resin contained in the insulating material for forming the sealing layer 290 includes, for example, epoxy resin, phenol resin, polyimide resin, and the like. The insulating material for forming the sealing layer 290 may contain a filler.

The filler contained in the insulating material for forming the sealing layer 290 includes, for example, an organic filler such as a silica filler or an alumina filler.

The sealing layer 290 may include only one layer, or may include a plurality of layers.

In the case where the sealing layer 290 includes a plurality of layers, the constituent materials of the plurality of layers may be the same, or may be different, or some of them may be different.

The sealing layer 290 is formed in such a manner as to seal the capacitor main body 210 by, for example, a method including thermally bonding an insulating resin sheet, a method including applying and then thermally curing an insulating resin paste, or the like.

The capacitor component 200 preferably further includes the via conductor 285 which penetrates the sealing layer 290 in the thickness direction T and is connected to the negative electrode layer 240 and the conductor wiring layer 270B.

The constituent material for forming the via conductor 285 includes, for example, a metal material containing a low-resistance metal such as copper, gold, or silver, and the like.

The via conductor 285 is formed by, for example, plating an inner-wall surface of a through-hole which penetrates the sealing layer 290 in the thickness direction T with the above-mentioned metal material, or by filling the through-hole with a conductive paste followed by heat treatment.

The sealing member 300 seals the core substrate 100 and the capacitor component 200.

The sealing member 300 includes a first sealing portion 310 and a second sealing portion 320 in the thickness direction T.

The first sealing portion 310 covers one surfaces (lower surfaces in FIG. 1) respectively of the core substrate 100 and the capacitor component 200 in the thickness direction T.

The second sealing portion 320 covers other surfaces (upper surfaces in FIG. 1) respectively of the core substrate 100 and the capacitor component 200 in the thickness direction T.

The sealing member 300 is preferably provided between the core substrate 100 and the capacitor component 200 in the plane direction.

The sealing member 300 may be integrated with the sealing layer 290 so that no interface exists between the sealing member 300 and the sealing layer 290, or does not have to be integrated with the sealing layer 290 so that an interface exists between the sealing member 300 and the sealing layer 290.

The sealing member 300 is preferably formed of an insulating material.

The insulating material for forming the sealing member 300 may contain an insulating resin, a prepreg, an inorganic material, a mixture of these, and the like.

The insulating resin contained in the insulating material for forming the sealing member 300 includes, for example, epoxy resin, phenol resin, polyimide resin, and the like.

The prepreg contained in the insulating material for forming the sealing member 300 includes, for example, resin-impregnated glass fibers (resin-impregnated glass cloth) and the like.

Regarding the prepreg contained in the insulating material for forming the sealing member 300, the diameter of the glass fibers (glass cloth) in the prepreg is preferably 3 μm to 15 μm.

Regarding the prepreg contained in the insulating material for forming the sealing member 300, the content of the resin in the prepreg is preferably 50% by weight to 90% by weight.

The inorganic material contained in the insulating material for forming the sealing member 300 includes, for example, glass and the like.

The constituent material of the sealing member 300 may be the same as or different from the constituent material of the base 110.

In the case where the base 110 and the sealing member 300 are both formed of a prepreg, the diameter of the glass fibers (glass cloth) in the prepreg, the density of the glass fibers (glass cloth) in the prepreg, the content of the resin in the prepreg, and the like may be the same or different between the base 110 and the sealing member 300.

The insulating material for forming the sealing member 300 may contain a filler.

The filler contained in the insulating material for forming the sealing member 300 includes, for example, an organic filler such as a silica filler or an alumina filler.

The sealing member 300 may include only one layer, or may include a plurality of layers.

In the case where the sealing member 300 includes a plurality of layers, the constituent materials of the plurality of layers may be the same, or may be different, or some of them may be different.

The sealing member 300 is formed in such a manner as to seal the core substrate 100 and the capacitor component 200 by, for example, a method including thermally bonding an insulating resin sheet, a method including applying and then thermally curing an insulating resin paste, or the like.

The capacitor embedded substrate 1 is manufactured as follows, for example. First, the core substrate 100 in which the opening 130 is provided in the thickness direction T and the capacitor component 200 are prepared. Next, the core substrate 100 is fixed on a supporting tape by attaching the core substrate 100 to the supporting tape at one surface (the lower surface in FIG. 1) thereof. Subsequently, the capacitor component 200 is put into the opening 130 of the core substrate 100, and is pressure-bonded to the supporting tape exposed inside the opening 130 of the core substrate 100 to fix the capacitor component 200 on the supporting tape. Then, a sealing member including the second sealing portion 320 is formed to seal from the other surfaces (upper surfaces in FIG. 1) of the core substrate 100 and the capacitor component 200 to the supporting tape, and then the supporting tape is removed.

Thereafter, a sealing member including the first sealing portion 310 is formed in such a manner as to come into contact with the sealing member formed beforehand while sealing the core substrate 100 and the capacitor component 200 from the one surfaces (the lower surfaces in FIG. 1), so that the sealing member 300 is obtained. In this way, the capacitor embedded substrate 1 is obtained.

When the capacitor embedded substrate 1 is manufactured as described above, for example, a characteristic positional relation appears between the core substrate 100 and the capacitor component 200. That is, in the capacitor embedded substrate 1, the one surface (the lower surface in FIG. 1) of the core substrate 100 and the one surface (the lower surface in FIG. 1) of the capacitor component 200 exist on the same plane (on the dashed line in FIG. 1). Specifically, the surface of the core substrate 100 on the first sealing portion 310 side and the surface of the capacitor component 200 on the first sealing portion 310 side exist on the same plane. In the example shown in FIG. 1, the surface of the core substrate 100 on the first sealing portion 310 side corresponds to the surface of the base 110 on the first sealing portion 310 side. In addition, in the example shown in FIG. 1, the surface of the capacitor component 200 on the first sealing portion 310 side corresponds to the surfaces of the conductor wiring layer 270A and the conductor wiring layer 270B on the first sealing portion 310 side. That is, in the example shown in FIG. 1, the surface of the base 110 on the first sealing portion 310 side and the surfaces of the conductor wiring layer 270A and the conductor wiring layer 270B on the first sealing portion 310 side exist on the same plane.

In the present Specification, the expression “the surface of one member and the surface of another member exist on the same plane” means that the maximum distance from the surface of the one member (for example, the core substrate) to the surface of the other member (for example, the capacitor component) in the thickness direction is 10 μm or less.

In the capacitor embedded substrate 1, a diameter R1a of the end portion of the through-hole 261A on the first sealing portion 310 side (hereinafter, also referred to simply as the diameter R1a) is larger than a diameter R2a of the end portion of the through-hole 261A on the second sealing portion 320 side (hereinafter, also referred to simply as the diameter R2a).

In the capacitor embedded substrate 1, a diameter R1b of the end portion of the through-hole 261B on the first sealing portion 310 side (hereinafter, also referred to simply as the diameter R1b) is larger than a diameter R2b of the end portion of the through-hole 261B on the second sealing portion 320 side (hereinafter, also referred to simply as the diameter R2b).

When the capacitor embedded substrate 1 is manufactured as described above, for example, the pressure in pressure-bonding the capacitor component 200 to the supporting tape is applied to the conductor wiring layer 270A on the supporting tape side, that is, the conductor wiring layer 270A on the first sealing portion 310 side. Against this, in the capacitor embedded substrate 1, since the diameter R1a of the through-hole 261A is larger than the diameter R2a as mentioned above, when the capacitor component 200 is pressure-bonded, the pressure applied to the conductor wiring layer 270A on the first sealing portion 310 side is dispersed, so that the conductor wiring layer 270A on the first sealing portion 310 side, in turn, the through conductor 260A on the end portion of which the conductor wiring layer 270A is provided becomes unlikely to be broken by cracks or the like. Moreover, in the capacitor embedded substrate 1, since the diameter R1a of the through-hole 261A is larger than the diameter R2a as mentioned above, that is, since the diameter of the through-hole 261A does not increase from the end portion on the first sealing portion 310 side to the end portion on the second sealing portion 320 side as a whole, the area of a portion where the electrostatic capacity can be expressed does not decrease in the capacitor component 200 (capacitor main body 210) as a whole, and as a result, a decrease in electrostatic capacity of the capacitor component 200 (capacitor main body 210) is suppressed.

In addition, when the capacitor embedded substrate 1 is manufactured as described above, for example, the pressure in pressure-bonding the capacitor component 200 to the supporting tape is applied to the conductor wiring layer 270B on the supporting tape side, that is, the conductor wiring layer 270B on the first sealing portion 310 side. Against this, in the capacitor embedded substrate 1, since the diameter R1b of the through-hole 261B is larger than the diameter R2b as mentioned above, when the capacitor component 200 is pressure-bonded, the pressure applied to the conductor wiring layer 270B on the first sealing portion 310 side is dispersed, so that the conductor wiring layer 270B on the first sealing portion 310 side, in turn, the through conductor 260B in which the conductor wiring layer 270B is provided on the end portion thereof becomes unlikely to be broken by cracks or the like. Moreover, in the capacitor embedded substrate 1, since the diameter R1b of the through-hole 261B is larger than the diameter R2b as mentioned above, that is, the diameter of the through-hole 261B does not increase from the end portion on the first sealing portion 310 side to the end portion on the second sealing portion 320 side as a whole, the area of a portion where the electrostatic capacity can be expressed does not decrease in the capacitor component 200 (capacitor main body 210) as a whole, and as a result, a decrease in electrostatic capacity of the capacitor component 200 (capacitor main body 210) is suppressed.

As described above, the capacitor embedded substrate 1 makes it possible to achieve a capacitor embedded substrate which is capable of suppressing a breakage of a through conductor (the through conductor 260A and the through conductor 260B in FIG. 1) and a conductor wiring layer provided on their end portions (the conductor wiring layer 270A and the conductor wiring layer 270B in FIG. 1) and a decrease in electrostatic capacity.

The diameter of the end portion of the through-hole on the first sealing portion side is determined by an equivalent circle diameter calculated from the area of the end portion as viewed in the thickness direction.

The diameter of the end portion of the through-hole on the second sealing portion side is determined by an equivalent circle diameter calculated from the area of the end portion as viewed in the thickness direction.

Although in the capacitor embedded substrate 1, both a relation A that “the diameter R1a is larger than the diameter R2a” and a relation B that “the diameter R1b is larger than the diameter R2b” are established, at least one of the relation A and the relation B may be established. That is, in the capacitor embedded substrate 1, only the relation A may be established, or only the relation B may be established, or both of the relation A and the relation B may be established as a preferable aspect.

As described above, in the capacitor embedded substrate of the present disclosure, in the case where there are a plurality of through-holes in which a through conductor and a conductor wiring layer are provided, the feature that “a diameter of an end portion of the through-hole on the first sealing portion side is larger than a diameter of an end portion of the through-hole on the second sealing portion side” only has to be established in at least one through-hole among the plurality of through-holes, and is particularly preferably established in all of the through-holes.

The diameter R1a and the diameter R1b may be equal or different.

The diameter R2a and the diameter R2b may be equal or different.

A diameter R3a of a portion which penetrates the capacitor main body 210 in the through-hole 261A is preferably smaller than the diameter R1a of the end portion of the through-hole 261A on the first sealing portion 310 side. In this case, since a decrease in area of a portion where the electrostatic capacity can be exhibited in the capacitor component 200 (capacitor main body 210) is sufficiently suppressed, a decrease in electrostatic capacity of the capacitor component 200 (capacitor main body 210) is sufficiently suppressed.

A diameter R3b of a portion which penetrates the capacitor main body 210 in the through-hole 261B is preferably smaller than the diameter R1b of the end portion of the through-hole 261B on the first sealing portion 310 side. In this case, since a decrease in area of the portion where the electrostatic capacity in the capacitor component 200 (capacitor main body 210) can be exhibited is sufficiently suppressed, a decrease in electrostatic capacity of the capacitor component 200 (capacitor main body 210) is sufficiently suppressed.

The diameter R3a of the portion which penetrates the capacitor main body 210 in the through-hole 261A is preferably smaller than the diameter R1a of the end portion of the through-hole 261A on the first sealing portion 310 side and the diameter R2a of the end portion of the through-hole 261A on the second sealing portion 320 side. In this case, since a decrease in area of the portion where the electrostatic capacity can be exhibited in the capacitor component 200 (capacitor main body 210) is significantly suppressed, a decrease in electrostatic capacity of the capacitor component 200 (capacitor main body 210) is significantly suppressed.

Note that the diameter R3a of the portion which penetrates the capacitor main body 210 in the through-hole 261A may be larger than the diameter R2a of the end portion of the through-hole 261A on the second sealing portion 320 side while being smaller than the diameter R1a of the end portion of the through-hole 261A on the first sealing portion 310 side. For example, regarding the through-hole 261B, in the example shown in FIG. 1, the diameter R3b of the portion which penetrates the capacitor main body 210 in the through-hole 261B is larger than the diameter R2b of the end portion of the through-hole 261B on the second sealing portion 320 side while being smaller than the diameter R1b of the end portion of the through-hole 261B on the first sealing portion 310 side.

Regarding the through-hole 261A, the sectional shape along the thickness direction T is not particularly limited as long as the diameter R1a of the end portion on the first sealing portion 310 side is larger than the diameter R2a of the end portion on the second sealing portion 320 side. The sectional shape of the through-hole 261A may be, for example, a constricted shape in which the diameter is smallest in the portion which penetrates the capacitor main body 210, or may be a tapered shape in which the diameter decreases from the end portion on the first sealing portion 310 side toward the end portion on the second sealing portion 320 side. In the example shown in FIG. 1, the sectional shape of the through-hole 261A is the above-mentioned constricted shape, which is a preferable aspect from the viewpoint of suppressing a decrease in area of the portion where the electrostatic capacity can be exhibited in the capacitor component 200 (capacitor main body 210).

Regarding the through-hole 261B, the sectional shape along the thickness direction T is not particularly limited as long as the diameter R1b of the end portion on the first sealing portion 310 side is larger than the diameter R2b of the end portion on the second sealing portion 320 side. The sectional shape of the through-hole 261B may be, for example, a constricted shape in which the diameter is smallest in the portion which penetrates the capacitor main body 210, or may be a tapered shape in which the diameter decreases from the end portion on the first sealing portion 310 side toward the end portion on the second sealing portion 320 side. In the example shown in FIG. 1, the sectional shape of the through-hole 261B is the above-mentioned tapered shape.

The sectional shapes of the through-hole 261A and the through-hole 261B may be the same or different.

The thickness of the core substrate 100 is preferably larger than the thickness of the capacitor component 200. In this case, when the core substrate 100 and the capacitor component 200 are sealed with the sealing member 300, the pressure applied from the sealing member 300 to the capacitor component 200 is likely to decrease, and breakage of the capacitor component 200 by the above pressure becomes unlikely to occur.

The coefficient of linear expansion of the base 110 in the plane direction is preferably 80% to 120% of the coefficient of linear expansion of the sealing member 300 in the plane direction. In this case, since the stress applied from the core substrate 100 and the sealing member 300 to the capacitor component 200 is likely to decrease, breakage of the capacitor component 200 by the above stress becomes unlikely to occur. Moreover, since the thermal properties of the core substrate 100 and the sealing member 300 become likely to be equalized, warpage of the capacitor embedded substrate 1 due to a difference in thermal property becomes unlikely to occur.

In the case where the coefficient of linear expansion of the base 110 in the plane direction is 80% to 120% of the coefficient of linear expansion of the sealing member 300 in the plane direction, the coefficient of linear expansion of the core portion 221 in the plane direction may be larger than 120% of the coefficient of linear expansion of the sealing member 300 in the plane direction. In this case, at the time of conducting a heat treatment on the capacitor embedded substrate 1, or the like, since the core substrate 100 and the sealing member 300 play roles of restricting the capacitor component 200, the thermal expansion and thermal contraction of the capacitor component 200 are sufficiently suppressed, and as a result, breakage of the through conductor (the through conductor 260A and the through conductor 260B in FIG. 1) and the conductor wiring layer (the conductor wiring layer 270A and the conductor wiring layer 270B in FIG. 1) provided on the end portion thereof is sufficiently suppressed.

Note that even in the case where the coefficient of linear expansion of the base 110 in the plane direction is not 80% or more or 120% or less of the coefficient of linear expansion of the sealing member 300 in the plane direction, the coefficient of linear expansion of the core portion 221 in the plane direction may be larger than 120% of the coefficient of linear expansion of the sealing member 300 in the plane direction. In this case as well, at the time of conducting a heat treatment on the capacitor embedded substrate 1, or the like, since the sealing member 300 plays a role of restricting the capacitor component 200, the thermal expansion and thermal contraction of the capacitor component 200 is suppressed, and as a result, breakage of the through conductor (the through conductor 260A and the through conductor 260B in FIG. 1) and the conductor wiring layer (the conductor wiring layer 270A and the conductor wiring layer 270B in FIG. 1) provided on the end portion thereof is suppressed.

In the case where the coefficient of linear expansion of the base 110 in the plane direction is 80% to 120% of the coefficient of linear expansion of the sealing member 300 in the plane direction, the coefficient of linear expansion of the core portion 221 in the plane direction may be 80% to 120% of the coefficient of linear expansion of the sealing member 300 in the plane direction. In this case, since the stress applied from the core substrate 100 and the sealing member 300 to the capacitor component 200 is more likely to decrease, breakage of the capacitor component 200 by the above stress becomes more unlikely to occur. Moreover, the thermal properties of the core substrate 100, the capacitor component 200, and the sealing member 300 become likely to be equalized, warpage of the capacitor embedded substrate 1 due to a difference in thermal property becomes unlikely to occur.

Note that even in the case where the coefficient of linear expansion of the base 110 in the plane direction is not 80% or more or 120% or less of the coefficient of linear expansion of the sealing member 300 in the plane direction, the coefficient of linear expansion of the core portion 221 in the plane direction may be 80% to 120% of the coefficient of linear expansion of the sealing member 300 in the plane direction. In this case as well, since the stress applied from the sealing member 300 to the capacitor component 200 is likely to decrease, breakage of the capacitor component 200 by the above stress becomes unlikely to occur. Moreover, since the thermal properties of the capacitor component 200 and the sealing member 300 become likely to be equalized, warpage of the capacitor embedded substrate 1 due to a difference in thermal property becomes unlikely to occur.

It is preferable that the coefficient of linear expansion of the base 110 in the plane direction be equal to the coefficient of linear expansion of the sealing member 300 in the plane direction, and the coefficient of linear expansion of the base 110 in the plane direction and the coefficient of linear expansion of the sealing member 300 in the plane direction be smaller than the coefficient of linear expansion of the core portion 221 in the plane direction. In this case, at the time of conducting a heat treatment on the capacitor embedded substrate 1, or the like, since the core substrate 100 and the sealing member 300 play roles of restricting the capacitor component 200, the thermal expansion and thermal contraction of the capacitor component 200 are sufficiently suppressed, and as a result, breakage of the through conductor (the through conductor 260A and the through conductor 260B in FIG. 1) and the conductor wiring layer (the conductor wiring layer 270A and the conductor wiring layer 270B in FIG. 1) provided on the end portion thereof is sufficiently suppressed.

It is preferable that the coefficient of linear expansion of the base 110 in the plane direction be smaller than the coefficient of linear expansion of the sealing member 300 in the plane direction, and the coefficient of linear expansion of the sealing member 300 in the plane direction be smaller than the coefficient of linear expansion of the core portion 221 in the plane direction. In this case, since the curing temperature (for example, thermal curing temperature) of the sealing member 300 having a coefficient of linear expansion in the plane direction larger than that of the base 110 is likely to be lower than the curing temperature (for example, thermal curing temperature) of the base 110, at the time of conducting a heat treatment on the capacitor embedded substrate 1, or the like, the core substrate 100 plays a role of restricting the capacitor component 200, and a failure or degradation in properties of the capacitor component 200 due to the heat in curing (for example, thermally curing) the sealing member 300 becomes unlikely to occur.

The coefficient of linear expansion of a target member (for example, the base, the core portion, the sealing member, or the like) in the plane direction of the capacitor embedded substrate may be a coefficient of linear expansion in any direction among the plane direction (for example, the first direction U or the second direction V in FIG. 1), and can be determined by a thermomechanical analysis (TMA) or a dynamic viscoelastic measurement (DMA). Note that in the case where it is difficult to directly take out (extract) the target member from the capacitor embedded substrate, it is possible to separately prepare a member for measurement formed of the same material as the constituent material of the target member and measure the coefficient of linear expansion of the member for measurement in the plane direction by the above-mentioned method.

The capacitor embedded substrate 1 may further include external electrode layers 400A which are provided on both surfaces of the sealing member 300 on the opposite sides in the thickness direction T and are electrically connected to the conductor wiring layer 270A. In this case, the external electrode layers 400A function as connection terminals of the capacitor embedded substrate 1. In the example shown in FIG. 1, the external electrode layers 400A function as connection terminals for the conductor wiring layer 270A, in turn, connection terminals for the positive electrode layer 220.

The constituent material of the external electrode layers 400A includes, for example, a metal material containing a low-resistance metal such as copper, gold, or silver, and the like.

The capacitor embedded substrate 1 may further include a via conductor 410A which penetrates the sealing member 300 in the thickness direction T and is connected to the conductor wiring layer 270A and the external electrode layer 400A.

The constituent material of the via conductor 410A includes, for example, a metal material containing low-resistance metal such as copper, gold, or silver, and the like.

The via conductor 410A is formed, for example, by plating an inner-wall surface of a through-hole which penetrates the sealing member 300 in the thickness direction T with the above-mentioned metal material, or conducting heat treatment after filling the through-hole with a conductive paste.

The capacitor embedded substrate 1 may further include external electrode layers 400B which are provided on both surfaces of the sealing member 300 on the opposite sides in the thickness direction T and are electrically connected to the conductor wiring layer 270B. In this case, the external electrode layers 400B function as connection terminals of the capacitor embedded substrate 1. In the example shown in FIG. 1, the external electrode layers 400B function as connection terminals for the conductor wiring layer 270B, in turn, connection terminals for the negative electrode layer 240.

The constituent material of the external electrode layer 400B includes, for example, a metal material containing a low-resistance metal such as copper, gold, or silver, and the like.

The constituent materials of the external electrode layers 400A and the external electrode layers 400B may be the same or different.

The capacitor embedded substrate 1 may further include a via conductor 410B which penetrates the sealing member 300 in the thickness direction T and is connected to the conductor wiring layer 270B and the external electrode layer 400B.

The constituent material of the via conductor 410B includes, for example, a metal material containing a low-resistance metal such as copper, gold, or silver, and the like.

The constituent materials of the via conductor 410A and the via conductor 410B may be the same or different.

The via conductor 410B is formed, for example, by plating an inner-wall surface of a through-hole which penetrates the sealing member 300 in the thickness direction T with the above-mentioned metal material, or conducting heat treatment after filling the through-hole with a conductive paste.

### Embodiment 2

In a capacitor embedded substrate of Embodiment 2 of the present disclosure, a capacitor component further includes a protection layer which covers at least part of at least one surface of a surface of the conductor wiring layer on the first sealing portion side and a surface of the conductor wiring layer on the second sealing portion side.

The capacitor embedded substrate of Embodiment 2 of the present disclosure is the same as the capacitor embedded substrate of Embodiment 1 of the present disclosure except for the above-described point.

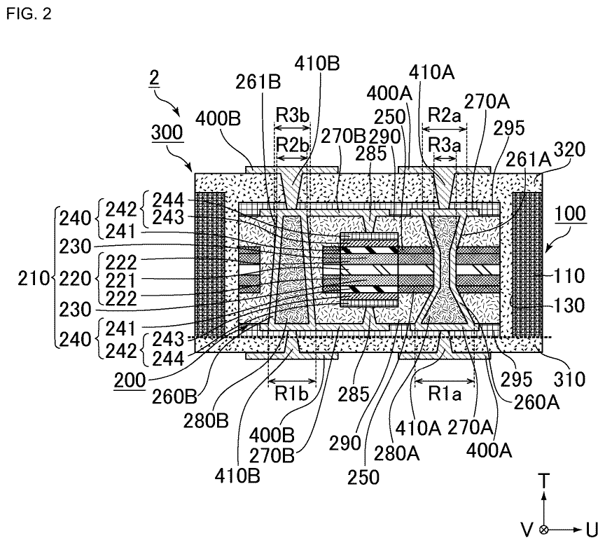

FIG. 2 is a sectional schematic diagram showing an example of the capacitor embedded substrate of Embodiment 2 of the present disclosure.

In the capacitor embedded substrate 2 shown in FIG. 2, a capacitor component 200 further includes a protection layer 295.

The protection layer 295 covers at least part of one surface of the surface of the conductor wiring layer 270A on the first sealing portion 310 side and the surface of the conductor wiring layer 270A on the second sealing portion 320 side. In the example shown in FIG. 2, the protection layer 295 covers both surfaces of the surface of the conductor wiring layer 270A on the first sealing portion 310 side and the surface of the conductor wiring layer 270A on the second sealing portion 320 side. This protects the conductor wiring layer 270A with the protection layer 295. Moreover, when the capacitor component 200 is press-bonded, since the pressure applied to the conductor wiring layer 270A on the first sealing portion 310 side is sufficiently dispersed, so that the conductor wiring layer 270A on the first sealing portion 310 side, in turn, the through conductor 260A in which the conductor wiring layer 270A is provided on the end portion thereof becomes more unlikely to be broken.

Note that the protection layer 295 may be provided only on one surface of the surface of the conductor wiring layer 270A on the first sealing portion 310 side and the surface of the conductor wiring layer 270A on the second sealing portion 320 side.

The protection layer 295 covers at least part of at least one surface of the surface of the conductor wiring layer 270B on the first sealing portion 310 side and the surface of the conductor wiring layer 270B on the second sealing portion 320 side. In the example shown in FIG. 2, the protection layer 295 covers both surfaces of the surface of the conductor wiring layer 270B on the first sealing portion 310 side and the surface of the conductor wiring layer 270B on the second sealing portion 320 side. This protects the conductor wiring layer 270B with the protection layer 295. Moreover, when the capacitor component 200 is press-bonded, the pressure applied to the conductor wiring layer 270B on the first sealing portion 310 side is sufficiently dispersed, so that the conductor wiring layer 270B on the first sealing portion 310 side, in turn, the through conductor 260B in which the conductor wiring layer 270B is provided on the end portion thereof becomes more unlikely to be broken.

Note that the protection layer 295 may be provided only on one surface among the surface of the conductor wiring layer 270B on the first sealing portion 310 side and the surface of the conductor wiring layer 270B on the second sealing portion 320 side.

The protection layer 295 is preferably provided from the surface of the conductor wiring layer 270A on the first sealing portion 310 side to the surface of the conductor wiring layer 270B on the first sealing portion 310 side. That is, the protection layer 295 is preferably provided across the entire surfaces of the conductor wiring layer 270A and the conductor wiring layer 270B on the first sealing portion 310 side. Specifically, the protection layer 295 is preferably provided in such a manner as to cover the entire surfaces of the conductor wiring layer 270A and the conductor wiring layer 270B on the first sealing portion 310 side.

The protection layer 295 is preferably provided from the surface of the conductor wiring layer 270A on the second sealing portion 320 side to the surface of the conductor wiring layer 270B on the second sealing portion 320 side. That is, the protection layer 295 is preferably provided across the entire surfaces of the conductor wiring layer 270A and the conductor wiring layer 270B on the second sealing portion 320 side. Specifically, the protection layer 295 is preferably provided in such a manner as to cover the entire surfaces of the conductor wiring layer 270A and the conductor wiring layer 270B on the second sealing portion 320 side.

It is particularly preferable that the protection layer 295 be provided from the surface of the conductor wiring layer 270A on the first sealing portion 310 side to the surface of the conductor wiring layer 270B on the first sealing portion 310 side, and be provided from the surface of the conductor wiring layer 270A on the second sealing portion 320 side to the surface of the conductor wiring layer 270B on the second sealing portion 320 side. That is, it is particularly preferable that the protection layer 295 be provided across the entire surfaces of the conductor wiring layer 270A and the conductor wiring layer 270B on the first sealing portion 310 side and across the entire surfaces of the conductor wiring layer 270A and the conductor wiring layer 270B on the second sealing portion 320. Specifically, it is particularly preferable that the protection layer 295 be provided in such a manner as to cover the entire surfaces of the conductor wiring layer 270A and the conductor wiring layer 270B on the first sealing portion 310 side and the entire surfaces of the conductor wiring layer 270A and the conductor wiring layer 270B on the second sealing portion 320 side.

The protection layer 295 is preferably placed on the entire capacitor main body 210 as viewed in the thickness direction T.

In the plane direction (the first direction U in FIG. 2), both ends of the protection layer 295 are preferably present at the same positions as both ends of the capacitor main body 210.

In the capacitor embedded substrate 2 as well, the one surface (the lower surface in FIG. 2) of the core substrate 100 and the one surface (the lower surface in FIG. 2) of the capacitor component 200 exist on the same plane (on the dashed line in FIG. 2) like the capacitor embedded substrate 1. In the example shown in FIG. 2, the one surface of the core substrate 100, specifically, the surface of the core substrate 100 on the first sealing portion 310 side corresponds to the surface of the base 110 on the first sealing portion 310 side. In addition, in the example shown in FIG. 2, the one surface of the capacitor component 200, specifically, the surface of the capacitor component 200 on the first sealing portion 310 side corresponds to the surface of the protection layer 295 on the first sealing portion 310 side. That is, in the example shown in FIG. 2, the surface of the base 110 on the first sealing portion 310 side and the surface of the protection layer 295 on the first sealing portion 310 side exist on the same plane.

The coefficient of linear expansion of the protection layer 295 in the plane direction is preferably 80% to 120% of the coefficient of linear expansion of the core portion 221 in the plane direction. In this case, since the stress applied from the protection layer 295 to the conductor wiring layer (the conductor wiring layer 270A and the conductor wiring layer 270B in FIG. 2), in turn, the stress applied from the protection layer 295 to the through conductor (the through conductor 260A and the through conductor 260B in FIG. 2) is likely to decrease, breakage of the through conductor (the through conductor 260A and the through conductor 260B in FIG. 2) by the above stress becomes unlikely to occur.

In the case where the coefficient of linear expansion of the protection layer 295 in the plane direction is 80% to 120% of the coefficient of linear expansion of the core portion 221 in the plane direction, the coefficient of linear expansion of the protection layer 295 in the plane direction is preferably larger than 120% of the coefficient of linear expansion of the sealing member 300 in the plane direction. In this case, at the time of conducting a heat treatment on the capacitor embedded substrate 2, or the like, since the sealing member 300 plays a role of restricting the capacitor component 200 including the protection layer 295, the thermal expansion and thermal contraction of the capacitor component 200 including the protection layer 295 are suppressed, and as a result, breakage of the through conductor (the through conductor 260A and the through conductor 260B in FIG. 2) and the conductor wiring layer (the conductor wiring layer 270A and the conductor wiring layer 270B in FIG. 2) provided on the end portion thereof is suppressed.

In the case where the coefficient of linear expansion of the protection layer 295 in the plane direction is 80% to 120% of the coefficient of linear expansion of the core portion 221 in the plane direction, the coefficient of linear expansion of the protection layer 295 in the plane direction is preferably larger than 120% of the coefficient of linear expansion of the base 110 in the plane direction. In this case, at the time of conducting a heat treatment on the capacitor embedded substrate 2, or the like, since the core substrate 100 plays a role of restricting the capacitor component 200 including the protection layer 295, the thermal expansion and thermal contraction of the capacitor component 200 including the protection layer 295 are suppressed, and as a result, breakage of the through conductor (the through conductor 260A and the through conductor 260B in FIG. 2) and the conductor wiring layer (the conductor wiring layer 270A and the conductor wiring layer 270B in FIG. 2) provided on the end portion thereof is suppressed.

It is particularly preferable that the coefficient of linear expansion of the protection layer 295 in the plane direction be 80% to 120% of the coefficient of linear expansion of the core portion 221 in the plane direction, and the coefficient of linear expansion of the protection layer 295 in the plane direction be larger than 120% of the coefficient of linear expansion of the sealing member 300 in the plane direction, and the coefficient of linear expansion of the protection layer 295 in the plane direction be larger than 120% of the coefficient of linear expansion of the base 110 in the plane direction. In this case, at the time of conducting a heat treatment on the capacitor embedded substrate 2, or the like, since the core substrate 100 and the sealing member 300 play roles of restricting the capacitor component 200 including the protection layer 295, the thermal expansion and thermal contraction of the capacitor component 200 including the protection layer 295 are sufficiently suppressed, and as a result, breakage of the through conductor (the through conductor 260A and the through conductor 260B in FIG. 2) and the conductor wiring layer (the conductor wiring layer 270A and the conductor wiring layer 270B in FIG. 2) provided on the end portion thereof is sufficiently suppressed.

In the case where the coefficient of linear expansion of the base 110 in the plane direction is equal to the coefficient of linear expansion of the sealing member 300 in the plane direction and the coefficient of linear expansion of the base 110 in the plane direction and the coefficient of linear expansion of the sealing member 300 in the plane direction are smaller than the coefficient of linear expansion of the core portion 221 in the plane direction, the coefficient of linear expansion of the protection layer 295 in the plane direction is preferably equal to the coefficient of linear expansion of the base 110 in the plane direction and the coefficient of linear expansion of the sealing member 300 in the plane direction. That is, it is preferable that the coefficient of linear expansion of the base 110 in the plane direction, the coefficient of linear expansion of the sealing member 300 in the plane direction, and the coefficient of linear expansion of the protection layer 295 in the plane direction be equal to one another, and the coefficient of linear expansion of the base 110 in the plane direction, the coefficient of linear expansion of the sealing member 300 in the plane direction, and the coefficient of linear expansion of the protection layer 295 in the plane direction be smaller than the coefficient of linear expansion of the core portion 221 in the plane direction. In this case, since the stress applied from the core substrate 100 and the sealing member 300 to the capacitor component 200 is likely to decrease, breakage of the capacitor component 200 by the above stress becomes unlikely to occur. Moreover, the stress applied from the protection layer 295 to the conductor wiring layer (the conductor wiring layer 270A and the conductor wiring layer 270B in FIG. 2), in turn, the stress applied from the protection layer 295 to the through conductor (the through conductor 260A and the through conductor 260B in FIG. 2) is likely to decrease, breakage of the through conductor (the through conductor 260A and the through conductor 260B in FIG. 2) by the above stress becomes unlikely to occur.

In the case where the coefficient of linear expansion of the base 110 in the plane direction is equal to the coefficient of linear expansion of the sealing member 300 in the plane direction and the coefficient of linear expansion of the base 110 in the plane direction and the coefficient of linear expansion of the sealing member 300 in the plane direction are smaller than the coefficient of linear expansion of the core portion 221 in the plane direction, the constituent material of the protection layer 295 is preferably the same as the constituent material of the sealing member 300. In this case, the machining, processing and the like on the sealing member 300 and the protection layer 295 are facilitated. For example, in forming the via conductor 410A and the via conductor 410B, laser machining for forming through-holes which penetrate the sealing member 300 and the protection layer 295 in the thickness direction T, desmear processing for removing residues generated at the time of the laser machining, plating processing for plating inner-wall surfaces of the through-holes with a metal material, and the like are facilitated.

In the case where the coefficient of linear expansion of the base 110 in the plane direction is smaller than the coefficient of linear expansion of the sealing member 300 in the plane direction and the coefficient of linear expansion of the sealing member 300 in the plane direction is smaller than the coefficient of linear expansion of the core portion 221 in the plane direction, the coefficient of linear expansion of the protection layer 295 in the plane direction is preferably equal to the coefficient of linear expansion of the base 110 in the plane direction. That is, it is preferable that the coefficient of linear expansion of the base 110 in the plane direction and the coefficient of linear expansion of the protection layer 295 in the plane direction be equal to each other, and the coefficient of linear expansion of the base 110 in the plane direction and the coefficient of linear expansion of the protection layer 295 in the plane direction be smaller than the coefficient of linear expansion of the sealing member 300 in the plane direction, and the coefficient of linear expansion of the sealing member 300 in the plane direction be smaller than the coefficient of linear expansion of the core portion 221 in the plane direction. In this case, at the time of conducting a heat treatment on the capacitor embedded substrate 1, or the like, the core substrate 100 restricts the capacitor component 200 and the protection layer 295 restricts portions other than the protection layer 295 of the capacitor component 200, the thermal expansion and thermal contraction of the capacitor component 200 are sufficiently suppressed, and as a result, breakage of the through conductor (the through conductor 260A and the through conductor 260B in FIG. 2) and the conductor wiring layer (the conductor wiring layer 270A and the conductor wiring layer 270B in FIG. 2) provided on the end portion thereof is sufficiently suppressed.

In the case where the coefficient of linear expansion of the base 110 in the plane direction is smaller than the coefficient of linear expansion of the sealing member 300 in the plane direction and the coefficient of linear expansion of the sealing member 300 in the plane direction is smaller than the coefficient of linear expansion of the core portion 221 in the plane direction, the constituent material of the protection layer 295 is preferably the same as the constituent material of the sealing member 300. In this case, the machining, processing, and the like on the sealing member 300 and the protection layer 295 are facilitated. For example, in forming the via conductor 410A and the via conductor 410B, laser machining for forming through-holes which penetrate the sealing member 300 and the protection layer 295 in the thickness direction T, desmear processing for removing residues generated at the time of the laser machining, plating processing for plating inner-wall surfaces of the through-holes with a metal material, and the like are facilitated.

The protection layer 295 is preferably formed of an insulating material.

The insulating material for forming the protection layer 295 may contain an insulating resin, a prepreg, an inorganic material, a mixture of these, and the like.

The insulating resin contained in the insulating material for forming the protection layer 295 includes, for example, epoxy resin, phenol resin, polyimide resin, and the like.

The prepreg contained in the insulating material for forming the protection layer 295 includes, for example, resin-impregnated glass fibers (resin-impregnated glass cloth) and the like.

Regarding the prepreg contained in the insulating material for forming the protection layer 295, a diameter of the glass fibers (glass cloth) in the prepreg is preferably 3 μm to 15 μm.

Regarding the prepreg contained in the insulating material for forming the protection layer 295, the content of the resin in the prepreg is preferably 50% by weight to 90% by weight.

The inorganic material contained in the insulating material for forming the protection layer 295 includes, for example, glass and the like.

The constituent material of the protection layer 295 may be the same as or different from the constituent material of the base 110.

In the case where the base 110 and the protection layer 295 are both formed of a prepreg, the diameter of the glass fibers (glass cloth) in the prepreg, the density of the glass fibers (glass cloth) in the prepreg, the content of the resin in the prepreg, and the like may be the same or different between the base 110 and the protection layer 295.

The constituent material of the protection layer 295 may be the same as or different from the constituent material of the sealing member 300. In the case where the constituent materials of the sealing member 300 and the protection layer 295 are the same, the machining, processing, and the like on the sealing member 300 and the protection layer 295 are facilitated. For example, in forming the via conductor 410A and the via conductor 410B, laser machining for forming through-holes which penetrate the sealing member 300 and the protection layer 295 in the thickness direction T, desmear processing for removing residues generated at the time of the laser machining, plating processing for plating inner-wall surfaces of the through-holes with a metal material, and the like are facilitated.

In the case where the sealing member 300 and the protection layer 295 are both formed of a prepreg, the diameter of the glass fibers (glass cloth) in the prepreg, the density of the glass fibers (glass cloth) in the prepreg, the content of the resin in the prepreg, and the like may be the same or different between the sealing member 300 and the protection layer 295.

The same protection layer 295 may be formed of only one layer or may be formed of a plurality of layers.

In the case where the same protection layer 295 is formed of a plurality of layers, the constituent materials of the plurality of layers may be the same, or may be different, or some of them may be different.

The protection layer 295 is formed in such a manner as to at least partially cover at least one surface of the surface of the conductor wiring layer 270A on the first sealing portion 310 side and the surface of the conductor wiring layer 270A on the second sealing portion 320 side by, for example, a method including thermally bonding an insulating resin sheet, a method including applying and then thermally curing an insulating resin paste, or the like.

In the capacitor embedded substrate 2, the protection layer 295 may be provided with an opening in the thickness direction T, and the opening of the protection layer 295 may be filled with the sealing member 300.

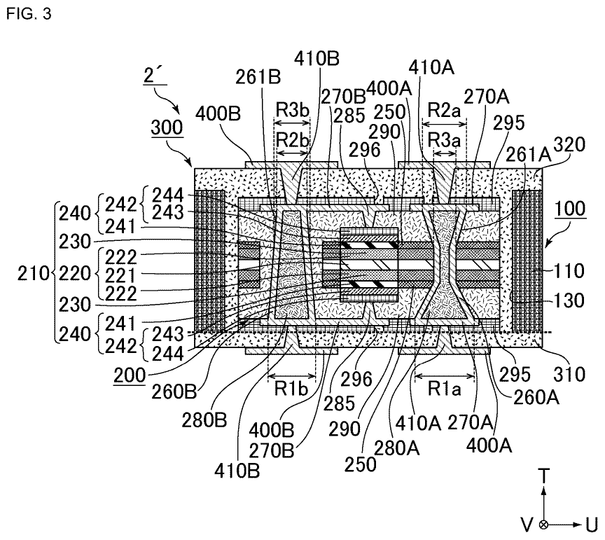

FIG. 3 is a sectional schematic diagram showing an example of a capacitor embedded substrate of modification of Embodiment 2 of the present disclosure.

In the capacitor embedded substrate 2′ shown in FIG. 3, the protection layer 295 is provided with an opening 296 in the thickness direction T. In the example shown in FIG. 3, the opening 296 penetrates the protection layer 295 in the thickness direction T. That is, in the example shown in FIG. 3, the opening 296 is provided in the protection layer 295 in the thickness direction T such that part of each of the conductor wiring layer 270A and the conductor wiring layer 270B is exposed.

The opening 296 of the protection layer 295 is filled with the sealing member 300. In the example shown in FIG. 3, the part of each of the conductor wiring layer 270A and the conductor wiring layer 270B, which is exposed in the opening 296 of the protection layer 295, is covered with the sealing member 300 put in the opening 296 of the protection layer 295. This increases the contact area of the sealing member 300 on the capacitor component 200, and the adhesion of the sealing member 300 on the capacitor component 200 is thus improved.

Note that the opening 296 does not have to penetrate the protection layer 295 in the thickness direction T. That is, the conductor wiring layer 270A or the conductor wiring layer 270B do not have to be exposed in the opening 296 of the protection layer 295.

The opening 296 of the protection layer 295 may have a hole shape (bore shape) or may have a slit shape (groove shape) as viewed in the thickness direction T.

The number of the opening 296 provided in the same protection layer 295 may be one or more.

In the case where a plurality of openings 296 are provided in the same protection layer 295, the plurality of openings 296 may be arranged regularly, or may be arranged irregularly as viewed in the thickness direction T.

### Embodiment 3

In a capacitor embedded substrate of Embodiment 3 of the present disclosure, a core substrate further includes an electrode which is provided on at least one surface of a surface of a base on the first sealing portion side and a surface of the base on the second sealing portion side.

The capacitor embedded substrate of Embodiment 3 of the present disclosure is the same as the capacitor embedded substrate of Embodiment 1 of the present disclosure except for the above-described point.

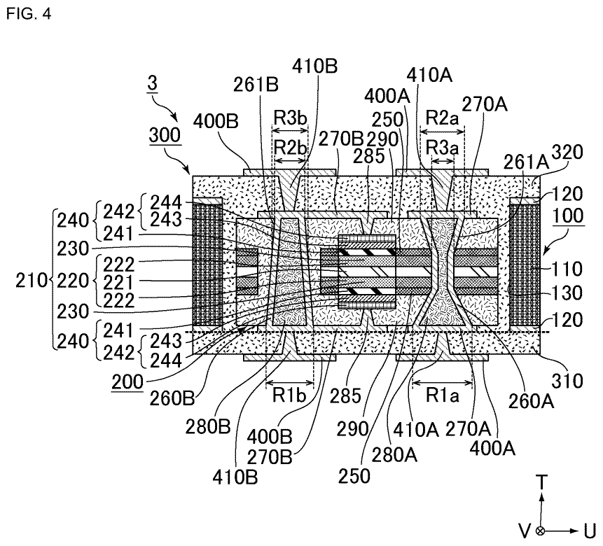

FIG. 4 is a sectional schematic diagram showing an example of the capacitor embedded substrate of Embodiment 3 of the present disclosure.

In the capacitor embedded substrate 3 shown in FIG. 4, the core substrate 100 further includes an electrode 120.

The electrode 120 is provided on at least one surface of a surface of the base 110 on the first sealing portion 310 side (a lower surface in FIG. 4) and a surface of the base 110 on the second sealing portion 320 side (an upper surface in FIG. 4). In the example shown in FIG. 4, the electrode 120 is provided on both surfaces of the surface of the base 110 on the first sealing portion 310 side and the surface of the base 110 on the second sealing portion 320 side.

Note that the electrode 120 may be provided on only one surface of the surface of the base 110 on the first sealing portion 310 side and the surface of the base 110 on the second sealing portion 320 side.

The constituent material of the electrode 120 includes, for example, a metal material containing a low-resistance metal such as copper, gold, or silver, and the like.

In the capacitor embedded substrate 3 as well, the one surface (the lower surface in FIG. 4) of the core substrate 100 and the one surface (the lower surface in FIG. 4) of the capacitor component 200 exist on the same plane (on the dashed line in FIG. 4) like the capacitor embedded substrate 1. In the example shown in FIG. 4, the one surface of the core substrate 100, specifically, the surface of the core substrate 100 on the first sealing portion 310 side corresponds to the surface of the electrode 120 on the first sealing portion 310 side. In addition, in the example shown in FIG. 4, the one surface of the capacitor component 200, specifically, the surface of the capacitor component 200 on the first sealing portion 310 side corresponds to the surfaces of the conductor wiring layer 270A and the conductor wiring layer 270B on the first sealing portion 310 side. That is, in the example shown in FIG. 4, the surface of the electrode 120 on the first sealing portion 310 side and the surfaces of the conductor wiring layer 270A and the conductor wiring layer 270B on the first sealing portion 310 side exist on the same plane.

### Embodiment 4

In a capacitor embedded substrate of Embodiment 4 of the present disclosure, a capacitor component further includes a protection layer which covers at least part of at least one surface of a surface of a conductor wiring layer on the first sealing portion side and a surface of the conductor wiring layer on the second sealing portion side, and a core substrate further includes an electrode provided on at least one surface of a surface of a base on the first sealing portion side and a surface of the base on the second sealing portion side.

The capacitor embedded substrate of Embodiment 4 of the present disclosure is the same as the capacitor embedded substrate of Embodiment 1 of the present disclosure except for the above-described point.

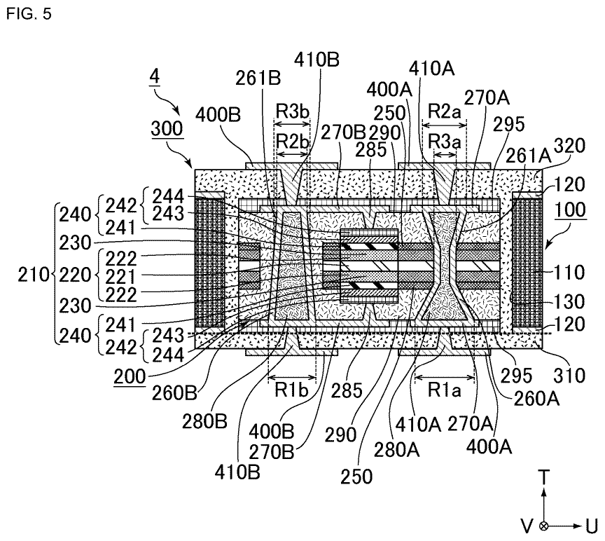

FIG. 5 is a sectional schematic diagram showing an example of the capacitor embedded substrate of Embodiment 4 of the present disclosure.

In the capacitor embedded substrate 4 shown in FIG. 5, a capacitor component 200 further includes a protection layer 295.

The aspect of the protection layer 295 in the capacitor embedded substrate 4 may be the same as the aspect of the protection layer 295 in the capacitor embedded substrate 2 (see FIG. 2). For example, in the capacitor embedded substrate 4, the protection layer 295 may be provided with an opening in the thickness direction T, and further the opening of the protection layer 295 may be filled with a sealing member 300. The aspect of the opening of such a protection layer 295 may be the same as the aspect of the opening 296 of the protection layer 295 in the capacitor embedded substrate 2′ (see FIG. 3).

In the capacitor embedded substrate 4, a core substrate 100 further includes an electrode 120.

The aspect of the electrode 120 in the capacitor embedded substrate 4 may be the same as the aspect of the electrode 120 in the capacitor embedded substrate 3 (see FIG. 4).

In the capacitor embedded substrate 4 as well, the one surface (the lower surface in FIG. 5) of the core substrate 100 and the one surface (the lower surface in FIG. 5) of the capacitor component 200 exist on the same plane (on the dashed line in FIG. 5) like the capacitor embedded substrate 1. In the example shown in FIG. 5, the one surface of the core substrate 100, specifically, the surface of the core substrate 100 on the first sealing portion 310 side corresponds to the surface of the electrode 120 on the first sealing portion 310 side. In addition, in the example shown in FIG. 5, the one surface of the capacitor component 200, specifically, the surface of the capacitor component 200 on the first sealing portion 310 side corresponds to the surface of the protection layer 295 on the first sealing portion 310 side. That is, in the example shown in FIG. 5, the surface of the electrode 120 on the first sealing portion 310 side and the surface of the protection layer 295 on the first sealing portion 310 side exist on the same plane.

In the capacitor embedded substrate of the present disclosure, the capacitor component (capacitor main body) is not limited to an electrolytic capacitor including the above-mentioned solid electrolytic capacitor. In the capacitor embedded substrate of the present disclosure, the capacitor component (capacitor main body) may form, for example, a ceramic capacitor using barium titanate, a thin-film capacitor using silicon nitride (SiN), silicon dioxide (SiO₂), hydrogen fluoride (HF), or the like, a trench capacitor having a MIM (Metal Insulator Metal) structure, or the like.

In the capacitor embedded substrate of the present disclosure, the capacitor component (capacitor main body) preferably forms a capacitor including a base of a metal such as aluminum, and more preferably forms an electrolytic capacitor including a base of a metal such as aluminum, from the viewpoint of a reduction in thickness and an increase in area of the capacitor component as well as an improvement in mechanical properties such as stiffness and flexibility of the capacitor component.

The capacitor embedded substrate of the present disclosure may be used for a composite electronic component, for example. Such a composite electronic component includes, for example, the capacitor embedded substrate of the present disclosure, and an electronic component which is electrically connected to the capacitor embedded substrate (for example, the external electrode layer) of the present disclosure.

The electronic component used in the composite electronic component may be a passive element, or may be an active element, or may be both of a passive element and an active element, or may be a complex of a passive element and an active element.

The passive element includes, for example, an inductor and the like.

The active element includes a memory, a GPU (Graphical Processing Unit), a CPU (Central Processing Unit), an MPU (Micro Processing Unit), a PMIC (Power Management IC), and the like.

In the case where the capacitor embedded substrate of the present disclosure is used for a composite electronic component, the capacitor embedded substrate of the present disclosure is used as a substrate for implementing electronic components, for example. In this case, by forming the capacitor embedded substrate of the present disclosure entirely into a sheet shape, and further forming electronic components which are implemented in the capacitor embedded substrate of the present disclosure into a sheet shape, it becomes possible to electrically connect the capacitor embedded substrate of the present disclosure and the electronic components in the thickness direction via through conductors which penetrate the electronic components in the thickness direction. As a result, it becomes possible to configure a passive element and an active element as electronic components like a module in overall.

For example, a switching regulator can be formed by electrically connecting the capacitor element of the present disclosure between a voltage regulator including a semiconductor active element and a load to which a converted direct-current voltage is supplied.

In a composite electronic component, it is also possible to form a circuit layer on the sealing member of the capacitor embedded substrate of the present disclosure and electrically connect the circuit layer to a passive element or an active element as an electronic component.

The present Specification discloses the following contents.
<1> A capacitor embedded substrate including: a core substrate that includes a base that defines an opening in a thickness direction thereof; a capacitor component in the opening of the core substrate; and a sealing member which seals the core substrate and the capacitor component, wherein the capacitor component includes a capacitor main body having a positive electrode layer with a core portion, a dielectric layer, and a negative electrode layer opposite to the positive electrode layer with the dielectric layer interposed therebetween in the thickness direction, a through conductor at least on an inner-wall surface of a through-hole penetrating at least the capacitor main body in the thickness direction, and a conductor wiring layer on first and second opposed end portions of the through conductor in the thickness direction, the sealing member includes a first sealing portion which covers first surfaces respectively of the core substrate and the capacitor component and a second sealing portion which covers second surfaces respectively of the core substrate and the capacitor component in the thickness direction, the first surface of the core substrate and the first surface of the capacitor component exist on a same plane, and a diameter of an end portion of the through-hole on a first sealing portion side is larger than a diameter of an end portion of the through-hole on a second sealing portion side.
<2> The capacitor embedded substrate according to <1>, in which a diameter of a portion of the through-hole which penetrates the capacitor main body is smaller than the diameter of the end portion of the through-hole on the first sealing portion side.
<3> The capacitor embedded substrate according to <2>, in which the diameter of the portion of the through-hole which penetrates the capacitor main body in the through-hole is smaller than the diameter of the end portion of the through-hole on the first sealing portion side and the diameter of the end portion of the through-hole on the second sealing portion side.
<4> The capacitor embedded substrate according to any one of <1> to <3>, in which a thickness of the core substrate is larger than a thickness of the capacitor component.
<5> The capacitor embedded substrate according to any one of <1> to <4>, in which a coefficient of linear expansion of the base in a plane direction perpendicular to the thickness direction is 80% to 120% of a coefficient of linear expansion of the sealing member in the plane direction.
<6> The capacitor embedded substrate according to any one of <1> to <5>, in which a coefficient of linear expansion of the core portion in a plane direction perpendicular to the thickness direction is larger than 120% of a coefficient of linear expansion of the sealing member in the plane direction.
<7> The capacitor embedded substrate according to any one of <1> to <5>, in which a coefficient of linear expansion of the core portion in a plane direction perpendicular to the thickness direction is 80% to 120% of a coefficient of linear expansion of the sealing member in the plane direction.
<8> The capacitor embedded substrate according to any one of <1> to <7>, in which the capacitor component further includes a protection layer which covers at least part of at least one of a surface of the conductor wiring layer on the first sealing portion side and a surface of the conductor wiring layer on the second sealing portion side.
<9> The capacitor embedded substrate according to <8>, in which a coefficient of linear expansion of the protection layer in a plane direction perpendicular to the thickness direction is 80% to 120% of a coefficient of linear expansion of the core portion in the plane direction.
<10> The capacitor embedded substrate according to <9>, in which the coefficient of linear expansion of the protection layer in the plane direction is larger than 120% of a coefficient of linear expansion of the sealing member in the plane direction.
<11> The capacitor embedded substrate according to <9> or <10>, in which the coefficient of linear expansion of the protection layer in the plane direction is larger than 120% of a coefficient of linear expansion of the base in the plane direction.
<12> The capacitor embedded substrate according to any one of <8> to <11>, in which the protection layer defines an opening therein in the thickness direction, and the opening of the protection layer is filled with the sealing member.
<13> The capacitor embedded substrate according to any one of <1> to <12>, in which the core substrate further includes an electrode on at least one of a surface of the base on the first sealing portion side and a surface of the base on the second sealing portion side.
<14> The capacitor embedded substrate according to any one of <1> to <13>, in which the positive electrode layer includes the core portion and a porous portion on at least one surface of the core portion in the thickness direction, the dielectric layer is on a surface of the porous portion, and the negative electrode layer is on a surface of the dielectric layer.

### REFERENCE SIGNS LIST

1, 2, 2′, 3, 4 CAPACITOR EMBEDDED SUBSTRATE
100 CORE SUBSTRATE
110 BASE
120 ELECTRODE
130 OPENING (CAVITY)
200 CAPACITOR COMPONENT
210 CAPACITOR MAIN BODY
220 POSITIVE ELECTRODE LAYER
221 CORE PORTION
222 POROUS PORTION
230 DIELECTRIC LAYER
240 NEGATIVE ELECTRODE LAYER
241 SOLID ELECTROLYTE LAYER
242 CONDUCTOR LAYER
243 CONDUCTIVE RESIN LAYER
244 METAL LAYER
250 MASK LAYER
260A, 260B THROUGH CONDUCTOR
261A, 261B THROUGH-HOLE
270A, 270B CONDUCTOR WIRING LAYER
280A, 280B RESIN-FILLED PORTION
285, 410A, 410B VIA CONDUCTOR
290 SEALING LAYER
295 PROTECTION LAYER
296 OPENING
300 SEALING MEMBER
310 FIRST SEALING PORTION
320 SECOND SEALING PORTION
400A, 400B EXTERNAL ELECTRODE LAYER
R1a, R1b DIAMETER OF AN END PORTION OF THE THROUGH-HOLE ON THE FIRST SEALING PORTION SIDE
R2a, R2b DIAMETER OF AN END PORTION OF THE THROUGH-HOLE ON THE SECOND SEALING PORTION SIDE
R3a, R3b DIAMETER OF A PORTION WHICH PENETRATES THE CAPACITOR MAIN BODY IN THE THROUGH-HOLE
T THICKNESS DIRECTION
U FIRST DIRECTION
V SECOND DIRECTION

1. A capacitor embedded substrate comprising:
a core substrate that includes a base that defines an opening in a thickness direction thereof;
a capacitor component in the opening of the core substrate; and
a sealing member which seals the core substrate and the capacitor component, wherein
the capacitor component includes a capacitor main body having a positive electrode layer with a core portion, a dielectric layer, and a negative electrode layer opposite to the positive electrode layer with the dielectric layer interposed therebetween in the thickness direction, a through conductor at least on an inner-wall surface of a through-hole penetrating at least the capacitor main body in the thickness direction, and a conductor wiring layer on first and second opposed end portions of the through conductor in the thickness direction,
the sealing member includes a first sealing portion which covers first surfaces respectively of the core substrate and the capacitor component and a second sealing portion which covers second surfaces respectively of the core substrate and the capacitor component in the thickness direction,
the first surface of the core substrate and the first surface of the capacitor component exist on a same plane, and
a diameter of an end portion of the through-hole on a first sealing portion side is larger than a diameter of an end portion of the through-hole on a second sealing portion side.

2. The capacitor embedded substrate according to claim 1, wherein a diameter of a portion of the through-hole which penetrates the capacitor main body is smaller than the diameter of the end portion of the through-hole on the first sealing portion side.

3. The capacitor embedded substrate according to claim 2, wherein the diameter of the portion of the through-hole which penetrates the capacitor main body is smaller than the diameter of the end portion of the through-hole on the second sealing portion side.

4. The capacitor embedded substrate according to claim 1, wherein a thickness of the core substrate is larger than a thickness of the capacitor component.

5. The capacitor embedded substrate according to claim 1, wherein a coefficient of linear expansion of the base in a plane direction perpendicular to the thickness direction is 80% to 120% of a coefficient of linear expansion of the sealing member in the plane direction.

6. The capacitor embedded substrate according to claim 1, wherein a coefficient of linear expansion of the core portion in a plane direction perpendicular to the thickness direction is larger than 120% of a coefficient of linear expansion of the sealing member in the plane direction.

7. The capacitor embedded substrate according to claim 1, wherein a coefficient of linear expansion of the core portion in a plane direction perpendicular to the thickness direction is 80% to 120% of a coefficient of linear expansion of the sealing member in the plane direction.

8. The capacitor embedded substrate according to claim 1, wherein the capacitor component further includes a protection layer which covers at least part of at least one of a surface of the conductor wiring layer on the first sealing portion side and a surface of the conductor wiring layer on the second sealing portion side.

9. The capacitor embedded substrate according to claim 8, wherein a coefficient of linear expansion of the protection layer in a plane direction perpendicular to the thickness direction is 80% to 120% of a coefficient of linear expansion of the core portion in the plane direction.

10. The capacitor embedded substrate according to claim 9, wherein the coefficient of linear expansion of the protection layer in the plane direction is larger than 120% of a coefficient of linear expansion of the sealing member in the plane direction.

11. The capacitor embedded substrate according to claim 9, wherein the coefficient of linear expansion of the protection layer in the plane direction is larger than 120% of a coefficient of linear expansion of the base in the plane direction.

12. The capacitor embedded substrate according to claim 8, wherein
the protection layer defines an opening therein in the thickness direction, and
the opening of the protection layer is filled with the sealing member.

13. The capacitor embedded substrate according to claim 1, wherein the core substrate further includes an electrode on at least one of a surface of the base on the first sealing portion side and a surface of the base on the second sealing portion side.

14. The capacitor embedded substrate according to claim 1, wherein
the positive electrode layer includes the core portion and a porous portion on at least one surface of the core portion in the thickness direction,
the dielectric layer is on a surface of the porous portion, and
the negative electrode layer is on a surface of the dielectric layer.

15. The capacitor embedded substrate according to claim 1, wherein
the through conductor is a first through conductor, the through-hole is a first through-hole penetrating, and the conductor wiring layer is a first conductor wiring layer,
the capacitor component further includes a second through conductor at least on an inner-wall surface of a second through-hole penetrating at least the capacitor main body in the thickness direction, and a second conductor wiring layer on first and second opposed end portions of the second through conductor in the thickness direction, and
a diameter of an end portion of the second through-hole on the first sealing portion side is larger than a diameter of an end portion of the second through-hole on the second sealing portion side.

16. The capacitor embedded substrate according to claim 15, wherein a diameter of a portion of the first through-hole which penetrates the capacitor main body is smaller than the diameter of the end portion of the first through-hole on the first sealing portion side, and a diameter of a portion of the second through-hole which penetrates the capacitor main body is smaller than the diameter of the end portion of the second through-hole on the first sealing portion side.

17. The capacitor embedded substrate according to claim 16, wherein the diameter of the portion of the first through-hole which penetrates the capacitor main body is smaller than the diameter of the end portion of the first through-hole on the second sealing portion side, and the diameter of the portion of the second through-hole which penetrates the capacitor main body is smaller than the diameter of the end portion of the second through-hole on the second sealing portion side.

18. The capacitor embedded substrate according to claim 15, wherein the capacitor component further includes a protection layer which covers at least part of at least one of a surface of the first conductor wiring layer on the first sealing portion side, a surface of the first conductor wiring layer on the second sealing portion side, a surface of the second conductor wiring layer on the first sealing portion side, and a surface of the second conductor wiring layer on the second sealing portion side.

19. The capacitor embedded substrate according to claim 18, wherein
the protection layer defines an opening therein in the thickness direction, and
the opening of the protection layer is filled with the sealing member.

20. The capacitor embedded substrate according to claim 15, wherein the core substrate further includes an electrode on at least one of a surface of the base on the first sealing portion side and a surface of the base on the second sealing portion side.
